(19) United States
(12) Patent Application Publication
(10) Pub. No.: US 2007/0252620 A1
(43) Pub. Date: Nov. 1, 2007

(54) PHASE OFFSET CONTROL PHASE-FREQUENCY DETECTOR

(75) Inventors: Paul H. Gailus, Prospect Heights, IL (US); Joseph A. Charaska, Melrose Park, IL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(73) Assignee: MOTOROLA, INC., Plantation, FL (US)

(21) Appl. No.: 11/380,901

(22) Filed: Apr. 28, 2006

(51) Int. Cl. H03D 13/00

(52) U.S. Cl. 327/3

(57) ABSTRACT

A phase-frequency detector (110) is provided. The phase-frequency detector can include a frequency counter delay (147) for counting cycles of an output signal to generate a divided variable frequency delayed signal (FVd 146) having a time shift. A control stage (200) coupled to the output stage generates a pump up control signal (222) and a pump down control signal (234) in response to receiving the FVd signal, a divided variable frequency signal (FV 136), and a reference frequency signal (FR 106). The time shift provides an overlap region that allows both source (350) and sink (360) currents to be provided in phase lock. In phase lock, the duration of the pump up control signal approximates the duration of the pump down control signal within a linear region of operation.

### FIELD OF THE INVENTION

The embodiments herein relate generally to phase-frequency detectors and more particularly to charge pump phase-frequency detectors used in phase lock loops.

### BACKGROUND

Fractional-N synthesizers are widely used in communications products because of their ability to achieve highly accurate frequency resolution together with relatively fast lock times. These synthesizers obtain this frequency resolution by generating an appropriate time sequence of integer loop divider numbers using delta-sigma modulation. A known technique for obtaining extremely fine frequency resolution in a phase lock loop (PLL) is to use a sigma delta modulator that modifies the value of N in a 1/N loop divider in the feedback loop of the frequency synthesizer. While the phase lock loop is in lock, the value of N is modified between two or more values, by use of a sequence of integer values that are typically low integer values. The sequence of integer values are coupled to the 1/N divider and an output of the 1/N loop divider is coupled to a phase-frequency detector. The sequence of integer values causes noise in the PLL that appears as modulation noise in the output of the PLL. An advantage of using a sigma delta modulator is that the phase quantization noise of the loop divider output is moved to higher frequencies which can be removed by a loop low-pass filter. The filtered low-pass response does not unfavorably modulate the output of the PLL.

It has been experimentally determined that the transfer function for a PLL that uses a sigma delta modulator in this fashion must be very linear to avoid undesirable sequence value dependent responses that degrade the noise shaping properties of the sigma delta modulator. A major factor that limits the sideband noise and spurious performance achieved by fractional-N synthesizer is this linearity of the phase detector. The nonlinearities can mix the high frequency quantization noise down to lower frequencies where there is minimal rejection from the low-pass loop filter.

The portion of the PLL that most typically introduces such non-linearities and the resultant degradation is the phase-frequency detector, which typically is a charge pump detector. In general, the charge pump phase detector is particularly attractive and has been widely used because of its relatively low noise, low current drain, and good frequency and phase acquisition characteristics. However, it suffers from nonlinearity due to the asymmetry in its response to input signals with phase lead versus those with phase lag. This can be problematic in fractional-N synthesizers because of the wide phase excursions presented to the phase detector even after phase lock has been acquired. Various approaches have been applied in the past to obtain sufficient phase detector linearity for use in fractional-N synthesizers. However, many known approaches use analog circuits that are sensitive to process parameters and reduce the yield and overall quality of radio products. These known methods also produce significant degradations in the noise and frequency and phase acquisition performance.

Two types of charge pump detectors have been used in the past. Although they have both been successfully employed, both of them have undesirable characteristics that are increasingly important in modern, very low power and high frequency devices, such as pagers and cellular phones. The first type is a tri-state charge pump phase-frequency detector. In this type of phase-frequency detector, a pump up switched current source and pump down switched current sink are coupled together forming a charge pump output. When an output of the 1/N divider lags a reference signal, the pump up current source is activated, and when the output of the 1/N divider leads the reference signal, the pump down current source is activated. When the PLL is in phase lock, either the source or sink is turned on during each cycle for a very brief time. This tri-state charge pump has an advantage of very low average current drain, but the operation of the tri-state charge pump degrades the noise shaping of the sigma delta modulator due to gain and transient characteristic differences between the current source and sink that introduce a non-linear performance. It is difficult in practice to match the gain differences and transient characteristics of the source and sink.

The second type of phase-frequency detector is a dual state phase-frequency detector, in which a pump up constant current source is on continuously and a pump down current sink having twice the value of the pump up constant current source is turned on when the output of the 1/N divider leads the reference signal. This results in a 50/50 duty cycle. Switching only the pump down sink results in a very linear charge pump output characteristic. Although this approach substantially reduces noise due to non-linearity, it generates undesirable noise from the constant current source and the switched current sink, which are active a large portion of the time. The high duty cycle is particularly a problem in CMOS devices which are desirable for their low cost but which inherently have high flicker noise. This has resulted in the use of expensive bipolar or BiCMOS processes in high performance applications.

Improvements to the tri-state charge pump phase-frequency detectors include creating an offset in the phase so that only up charge pump pulses or only down charge pump pulses are produced when the fractional-N synthesizer has reached steady state. The phase offset is at least as large as the edge-to-edge phase deviation of the loop divider output as the fractional-N synthesizer jumps between different integer divide numbers. While effective for improving the phase detector linearity, such known approaches introduce a number of problems. One known technique (U.S. U.S. Pat. No. 6,002,273 and U.S. Pat. No. 6,605,935) introduces a sufficiently large bias current in one direction to cause all of the output current pulses to be always in the opposite direction. However, this current introduces additional noise without contributing to the desired signal output level. Furthermore, the phase offset induced by this bias current does not have any direct or controlled relationship to the amount of phase deviation at the loop divider output. Therefore, in order to ensure unidirectional current pulses under IC process variations, an extra quantity of bias current needs to be allocated and this degrades the noise performance even more. Another known method technique (U.S. U.S. Pat. No. 6,002,273 and U.S. Pat. No. 6,605,935) generates a phase offset by delaying internal phase detector signals by using an analog delay element comprised of strings of inverter gates, resistor-capacitor networks, or transistor-capacitor networks. However, these techniques introduce significant added noise levels due to the slowing of signal edges. Accordingly, there is a need for an improved phase-frequency detector.

### SUMMARY

Embodiments of the invention can concern a phase-frequency detector and in a particular embodiment a linear phase-frequency detector with a wider range that reduces the coupling of device noise into the PLL output and that is independent of device operating conditions and parameters. The phase-frequency detector can include an input for a reference frequency signal (FR), an input for a divided variable frequency signal (FV), an output stage for generating an output signal, a variable frequency delay counter for counting cycles of a loop divider input signal and delaying the FV signal by a predetermined number of cycles to generate a divided variable frequency delayed signal (FVd), a control stage coupled to the output stage that generates a pump up control signal and a pump down control signal in response to receiving the FR, FV, and FVd signals. When FV leads FR by a lead time and FVd lags FR by a lag time, the control stage can generate the pump down control signal having an active state with a duration that is essentially equal to the lead time, and generate the pump up control signal having an active state with a duration essentially equal to the lag time. In one arrangement, the variable frequency delay counter can count the cycles from a loop divider input signal provided by a variable frequency oscillator and thereby generate FVd

Embodiments of the invention can also concern a phased lock loop. The phased lock loop can include a phase-frequency detector that comprises a first input to a control stage that receives a reference frequency signal (FR), a second input to the control stage that receives a divided variable frequency signal (FV), a third input to the control stage that receives a divided variable frequency delayed signal (FVd) signal, and an output stage coupled to the control stage, wherein the output stage generates an output signal having a current in proportion to a phase difference between FR and FV. The phase locked loop can include a variable frequency delay counter for counting cycles of a loop divider input signal and delaying an FV signal by a predetermined number of cycles to generate a divided variable frequency delayed signal (FVd) signal. The control stage can generate a pump up control signal and a pump down control signal, in response to a divided variable frequency signal (FV), a reference frequency signal (FR) and the FVd signal. During a phase lock, the pump up control signal can source a first current and the pump down control signal sinks a second current that contribute a substantially equal amount to a gain of the output signal when the first current and the second current are approximately equal. The linearity of the phase-frequency detector can be maintained when the first current and the second current are mismatched.

Embodiments of the invention can also concern an electronic equipment including a phase-frequency detector having an output stage. The electronic equipment can include a pump up switched current source coupled to a charge pump output node that sources a first current, I1, in response to a pump up control signal, a pump down switched current sink coupled to the charge pump output node that sinks a second current, I2, in response to a pump down control signal, and a control stage coupled to the output stage that generates, in response to a divided variable frequency delayed signal, a divided variable frequency signal (FV), and a reference frequency signal (FR), a pump up control signal and a pump down control signal. During a phase lock the pump up control signal can source a first current and the pump down control signal sink a second current that contribute a substantially equal amount to a gain of the output signal when the first current and the second current are approximately equal. The control stage can include a variable frequency delay counter for counting cycles of the loop divider input signal to generate a divided variable frequency delayed signal (FVd), wherein during the phase lock, the duration of the pump up control signal can be essentially equal to the duration of the pump down control signal.

### BRIEF DESCRIPTION OF THE DRAWINGS

The features of the system, which are believed to be novel, are set forth with particularity in the appended claims. The embodiments herein, can be understood by reference to the following description, taken in conjunction with the accompanying drawings, in the several figures of which like reference numerals identify like elements, and in which:

FIG. 1 is an electrical block diagram of a phase lock loop circuit that includes a phase-frequency detector, in accordance with the preferred embodiment of the present invention;

FIG. 2 is an electrical block diagram of a control stage and an output stage of the phase-frequency detector, in accordance with the preferred embodiment of the present invention;

FIG. 3 is a graph of average current supplied by the phase-frequency detector versus phase lag and phase lead in accordance with the preferred embodiment of the present invention.

FIG. 4 is a timing diagram which illustrates signals generated by the control stage when the phase lock loop has substantially acquired lock such that the lead time and lag time are equal, in accordance with the preferred embodiment of the present invention;

FIG. 5 is a timing diagram which illustrates the signals generated by the control stage when the lead time is less than the lag time in accordance with the preferred embodiment of the present invention; and

FIG. 6 is a timing diagram which illustrates the signals generated by the control stage when the lead time is greater than the lag time, in accordance with the preferred embodiment of the present invention.

### DETAILED DESCRIPTION

While the specification concludes with claims defining the features of the embodiments of the invention that are regarded as novel, it is believed that the method, system, and other embodiments will be better understood from a consideration of the following description in conjunction with the drawing figures, in which like reference numerals are carried forward.

As required, detailed embodiments of the present method and system are disclosed herein. However, it is to be understood that the disclosed embodiments are merely exemplary, which can be embodied in various forms. Therefore, specific structural and functional details disclosed herein are not to be interpreted as limiting, but merely as a basis for the claims and as a representative basis for teaching one skilled in the art to variously employ the embodiments of the present invention in virtually any appropriately detailed structure. Further, the terms and phrases used herein are not intended to be limiting but rather to provide an understandable description of the embodiment herein.

The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically. The term “suppressing” can be defined as reducing or removing, either partially or completely. The term “processing” can be defined as number of suitable processors, controllers, units, or the like that carry out a pre-programmed or programmed set of instructions.

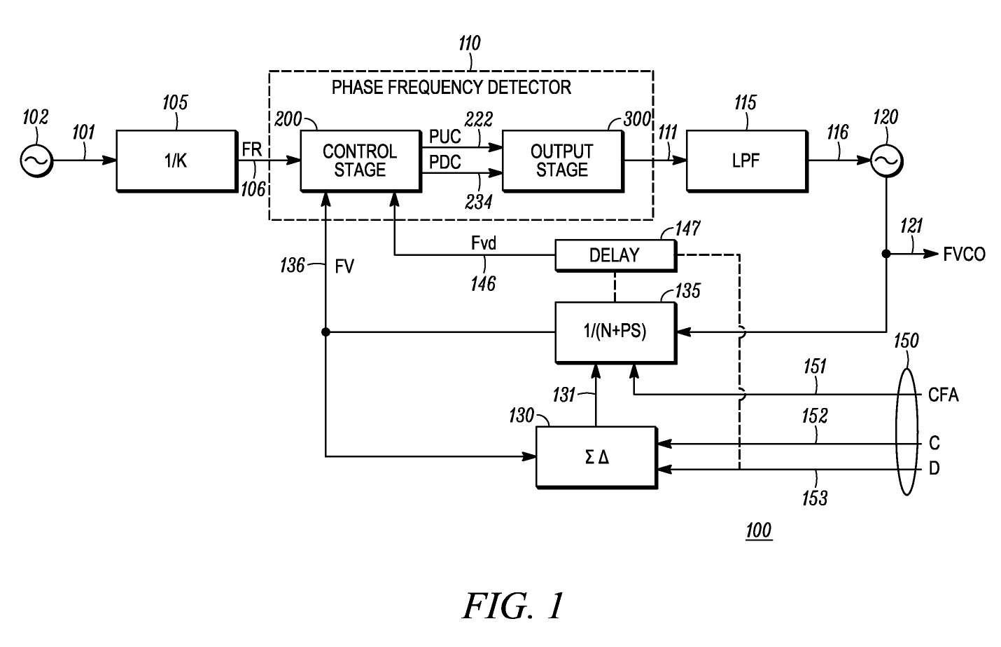

Referring to FIG. 1, an electrical block diagram of a phase lock loop 100 that includes a linear, low noise, phase-frequency detector is shown, in accordance with the preferred embodiment of the present invention. The phase look loop 100 comprises a reference oscillator 102 that generates a signal 101 that is coupled to a divider 105 that can be set at a fixed division ratio for a given carrier frequency. The divider 105 converts the signal 101 to a reference frequency signal (FR) 106 that is coupled to a phase-frequency detector 110. The phase-frequency detector 110 generates an output current, 111, that is coupled to a low pass filter 115. A filtered output signal 116 from the low pass filter 115 is coupled to a voltage controlled oscillator 120 that generates an output signal (Fvco) 121. The voltage controlled oscillator 120 can have a frequency that is determined by an input control 150 comprising three signals: a coarse frequency adjust (CFA) signal 151, a numerator value (C) 152, and a denominator value (D) 153. The CFA signal 151 is coupled to an input of a divider 135 and sets a base value of division, N, of the fractional divider 135. The fractional divider 135 is also coupled to a sequence of values 131 generated by a sigma delta modulator 130. The divider 135 has a loop divider input coupled to Fvco 121, and divides the frequency of Fvco 121 by the value N plus a most recent value received in the sequence of values 131. The values in the sequence of values 131 are zeros and ones, but could alternatively be other small integer values. As a result, the divider 135 generates a divided variable signal (FV) 136 that has an average frequency determined by the CFA signal 151 and the sequence of values 131. The sequence of values 131, when averaged over a large number of cycles of the FV signal 136, has an average value between 0 and +1. Thus, the FV signal 136 has an average frequency determined by an average value of the divider 135, the average value being between N and N+1. For example, performing three successive divisions by 20 followed by one division by 21 results in an average division factor of (3*20+21)/4=20.25. Due to the repetitive nature of the variable modulus division, however, spurious tones will be generated that will modulate the signal FVCO 121.

To address these problems, sigma delta modulators have been employed to shape the spurious response of the fractional-N divider. A typical sigma delta noise density distribution reveals that the spurious tone is replaced by a spectrum of spurious tones with most of the spurious energy being pushed out in frequency, well beyond the bandwidth of the phase locked loop. As a result of the shaping performed by the sigma delta modulator, this spurious energy will have a substantially reduced effect on the output signal from the PLL 100. The sigma delta modulator stage 130 generates the sequence of values 131 based on the ratio of the numerator value 152 to the denominator value 153, and generated at a rate determined by the FV signal 136, which is coupled to an input of the sigma delta modulator 130 and to an input of the phase-frequency detector 110.

In general, the loop divider 135 can be a counter or a series of counters depending on the specific application. The output (FV 136) of the loop divider can be synchronized to the loop divider input signal (Fvco 121) to minimize end to end delay. Also for example, in high frequency synthesizers, a programmable counter can be preceded by a prescaler, wherein the prescaler is another type of counter designed to operate at high frequencies.

Prescalers are specifically designed to count (divide) to a predetermined set of VCO cycles, under control of a modulus control signal, such as a) dual modulus prescalers; 7 or 8, 15 or 16, or b) modulus four; 4, 5, 6, or 7. The modulus control signal instructs the prescaler when to count to one of the available numbers in the set. The prescaler can be programmed at the beginning of the counter's cycle to determine which count number is to be used. In practice, the modulus control signal can be generated by the programmable counter.

A prescaler can operate similarly to a programmable counter and which produces an output that is generally synchronized to the input. For example, a rising edge of the loop divider input signal from the VCO 120 triggers the output event. In this way the delay of the counter is minimized.

Synchronization of the loop counter's output (FV 136) with that of its input (Fvco 121) is an important technique for minimizing the noise contribution of the counter in the loop divider 135. Synchronization can be achieved by controlling the counter's output with the counter's input. For example, a count up counter will increment on an edge of the input signal until the maximum count is reached, then on the next input event, a carry (overflow) signal will be produced. This carry signal can be used to load the starting state of the next count into the counter and produce the output.

The phase-frequency detector 110 also includes an input from a variable frequency delay counter 147. The variable frequency delay counter 147 can include a prescaler for achieving an accurate count of cycles input to the loop divider 135. In another arrangement, the variable frequency delay counter 147 can be cooperatively coupled to the loop divider 135 of the input control 150 for identifying cycles of Fvco 121. Alternatively, the variable frequency delay counter 147 can be integrated or configured to operate within the loop divider 135. The variable frequency delay counter 147 can generate a phase offset relative to the FV signal 136 that is directly proportional to a cycle of the loop divider input signal. The FVd signal 146 can be a delayed replica of the FV signal 126, wherein the delay is a predetermined number of Fvco 121 cycles.

In practice, the variable frequency delay counter 147 can generate the divided variable frequency delay signal (FVd 146) with decoding logic on the existing counters within the loop divider 135. The variable frequency delay counter 147 can incorporate a prescaler for achieving the precise timing resolution associated with counting a number of cycles of the Fvco 121 For example, the variable frequency delay counter 147 counts cycles of the output signal and generates a carry flag on an integer number of counted cycles. The carry flag triggers the control stage to establish the duration for one of the pump control signals. The integer number of counted cycles can be a programmable time shift relative to the FV signal. Alternatively, the variable frequency delay counter 147 can be a standalone unit that precisely measures cycles of Fvco 121 directly.

In one arrangement, the variable frequency delay counter 147 is included within the loop divider 135 which itself may have a count up loop counter. The loop divider 135 outputs both FV 136 and FVd 146 to the phase-frequency detector 110. In one aspect, combinational logic is employed to detect the occurrence of a state that succeeds the carry (overflow) by a predetermined (or programmable) number of counts. This FVd 146 output, like the traditional output FV 136, is synchronized to the Fvco 121 output; that is, the input to the loop divider 135.

The variable frequency delay counter 147 provides a well-controlled and programmable time shift, T, relative to the loop divider 135 output signal FV 136. The time shift creates a region in the phase detector transfer function such that output pulses PUC and PDC, which source current and sink current, are both provided when the loop has locked. As a result, the phase detector 110 can be highly linear for phase excursions confined to this region. The time shift T can be programmed to be at least the maximum edge-to-edge timing jitter of signal FV for the particular synthesizer configuration and operating parameters selected to ensure linear operation. For example, the operating parameters can include the number of accumulators, the divide number programming words, and the like. A programmable integer number of Fvco cycles, or half cycles, can be provided as the delay or advance. For example, the variable frequency delay counter 147 can count the number of Fvco cycles or half cycles to produce the delay. This allows the transitions of FVd to be precisely controlled by the transitions of the Fvco signal 121.

The variable frequency delay counter 147 produces an output signal that is synchronized to the Fvco signal 121 and to the loop divider output FV 136 and is independent of actual IC device process parameters or operating conditions. The variable frequency delay counter 147 can generate a phase offset that is directly proportional to a Fvco cycle for operating the phase detector within a linear region over these phase deviations. The variable frequency delay counter 147 provides precise control of phase offset which reduces the amount of extra offset generally required in integrated circuit (IC) design. This results in excellent tracking of the phase deviations over IC process variations.

The general architecture of the phase lock loop of FIG. 1 is conventional, and all of the elements described above with reference to FIG. 1 are conventional, except for the unique phase-frequency detector 110. In one arrangement, the phase-frequency detector 110 can be implemented in one integrated circuit. The low pass filter 115 comprises a capacitor that integrates the output signal of the output stage 300, and the low pass filter 115 suppresses high frequency noise components generated by the sequence of values 131 that vary the divisor in the divider 135. The phase-frequency detector 110 comprises a control stage 200 that is coupled to an output stage 300 by a pump up control (PUC) signal 222 and a pump down control (PDC) signal 234.

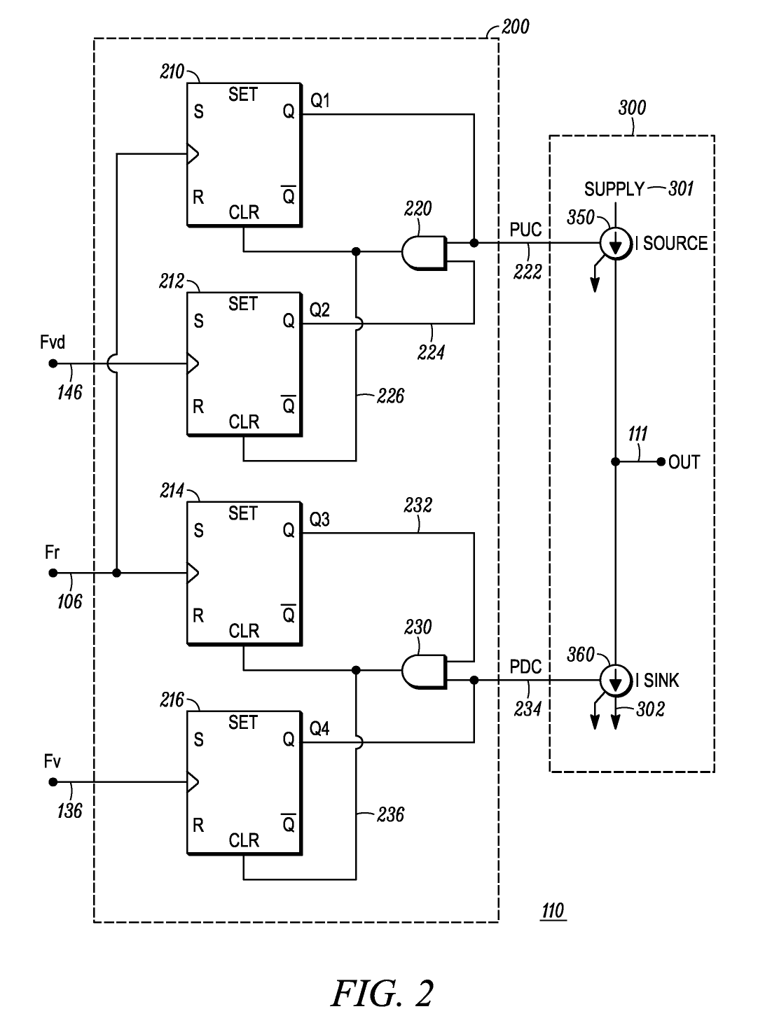

Referring to FIG. 2, an electrical block diagram of the control stage 200 and the output stage 300 of the phase-frequency detector 110 is shown in accordance with the preferred embodiment of the present invention. The control stage 200 comprises a first flip-flop 210 that has a clock input coupled to the FR signal 106. The first flip-flop 210 sets a pump up control (PUC) signal 222 that is generated at a first output (Q1) to an active state (a logic high in this embodiment) in response to a rising edge of the FR signal 106. A second flip-flop 212 has a clock input coupled to the Fvd signal 146. The second flip-flop 212 sets a trigger up signal 224 that is generated at a second output (Q2) to an active state in response to a rising edge of the FVd signal 146. A third flip-flop 214 has a clock input coupled to the FR signal 106. The third flip-flop 214 sets a trigger down signal 232 that is generated at a third output (Q3) to an active state in response to a rising edge of the Fr signal 106. A fourth flip-flop 216 has a clock input coupled to the FV signal 136. The fourth flip-flop 216 sets a trigger down signal 232 that is generated at a third output (Q3) to an active state in response to a rising edge of the Fr signal 106. The fourth flip-flop 216 sets a pump down control PDC signal 234 generated at a fourth output (Q4) to the active state in response to a rising edge of the FV signal 136.

The control stage 200 also comprises a first AND gate 220 that has the PUC signal 222 and trigger up signal 224 coupled thereto as inputs. The first flip-flop 210 has a first reset input that is coupled to a reset up (RU) signal 226 generated by the output of the first AND gate 220. The second flip-flop 212 has a second reset input that is also coupled to the reset up (RU) signal 226 generated by the output of the first AND gate 220. The control stage 200 also comprises a second AND gate 230 that has the trigger down signal 232 and the PDC signal 234 coupled thereto as inputs. The third flip-flop 214 has a third reset input that is coupled to a reset down (RD) signal 236 generated by the output of the second AND gate 230. The fourth flip-flop 216 has a fourth reset input that is also coupled to the reset up (RD) signal 236 generated by the output of the second AND gate 220. All of the logic circuits 210,212, 214, 216, 220, and 230 can be fabricated from standard CMOS logic.

The output stage 300 can comprise a pump up switched current source coupled to a charge pump output node that sources a first current, I1, in response to a pump up control signal, a pump down switched current sink coupled to the charge pump output node that sources a second current, I2, in response to a pump down control signal, at the charge pump output node. For example, the output stage 300 can include a pump up switched current source 350 that sources a current of a first value, I₁, at a pump output node 111 when a PUC signal 222 is in an active state. The output stage 300 also comprises a pump down switched current sink 360 that sinks a current of a second value, I₂, at the pump output node 111 when PDC signal 234 is in an active state. The switched current source 350 is supplied by a power supply 301, and the switched current sink sinks its current into a ground reference 302 of the power supply. In one arrangement, the switched current source 350 can comprise a switch FET coupled in series with a source FET, and the switched current sink 360 can comprise a switch FET coupled in series with a sink FET. The FETs can be implemented in CMOS. In accordance with the preferred embodiment of the present invention, I₁ is approximately equal to I₂. The currents I₁ and I₂ are designed to be approximately equal by using conventional techniques to produce equivalent geometries in FET devices, and also by driving them from a conventional current mirror that may be common to the FETs. Thus, the currents I₁ and I₂ can be matched to within the tolerances of standard CMOS processes.

The PUC signal 222 in an active state (a logic high) generates a source current which results in an UP pulse. The PDC signal 234 in an active state (a logic high) generates a sink current which results in a DOWN pulse. The PUC and PDC signals are both logic high when in the active mode. In practice, when the PLL 100 has acquired lock, both the UP pulses (source currents) and DOWN pulses (sink currents) will contribute a substantially equal amount to a gain of the phase detector 110 as long as their currents are reasonably matched to each other. During a phase lock the pump down control signal and the pump up control can contribute an approximately equal amount of gain to the output signal when the first current and the second current are approximately the same. The architecture of the control stage 200 also allows for mismatches in the UP versus DOWN currents. Mismatch between currents will not degrade the linearity of the phase detector and the spectral purity of the synthesizer, as both the UP and the DOWN pulses are each spectrally shaped by delta-sigma modulation.

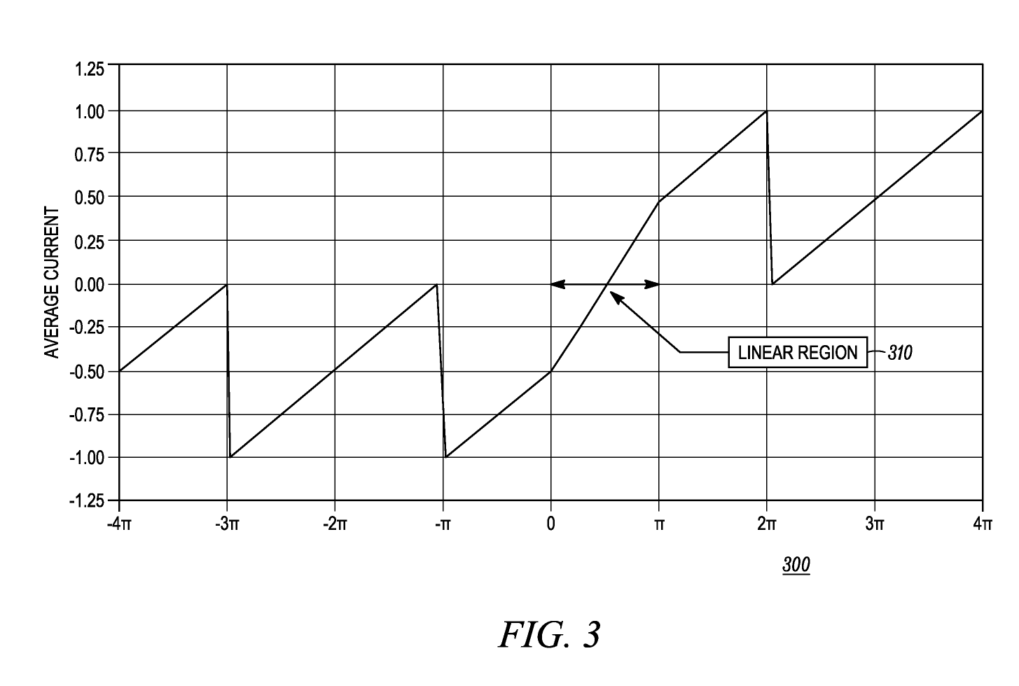

Referring to FIG. 3, a graph of the average output current 111 supplied by the phase-frequency detector 110 is shown in accordance with a preferred embodiment of the present invention. FIG. 3 reveals that the output current is linear (310) when the phase excursions are confined between 0 to x, which is a typical range of operation. The phase detector 110 exhibits a linear response to changes in phase when the phase excursions are confined to this range. It should be noted, that a mismatch in the currents I₁ and I₂ do not affect the linearity of the phase detector 110. The linearity of the phase detector 110 due to the configuration of the elements in the control stage 200 is robust to mismatches in source and sink currents which is an advantage over prior art systems. For example, nonlinearities are generally a result of these current mismatches, which develop as a result of disproportionate charge injection for phase differences having equal but opposite direction. For example, in response to a phase lag, current is sourced, and in response to a phase lead, current is sunk. The amount of current sourced for a phase lag having a fixed difference should be the same amount of current sunk for a phase lead having the same fixed difference. When the amount of current is not the same (i.e. mismatched), the disproportionate charge leads to a mismatch in current and thereby producing a non-linear response. However, the configuration of the control stage 200 is such that the source current and the sink current when activated are not concurring in time; that is, there is no overlap in currents to cause a current mismatch.

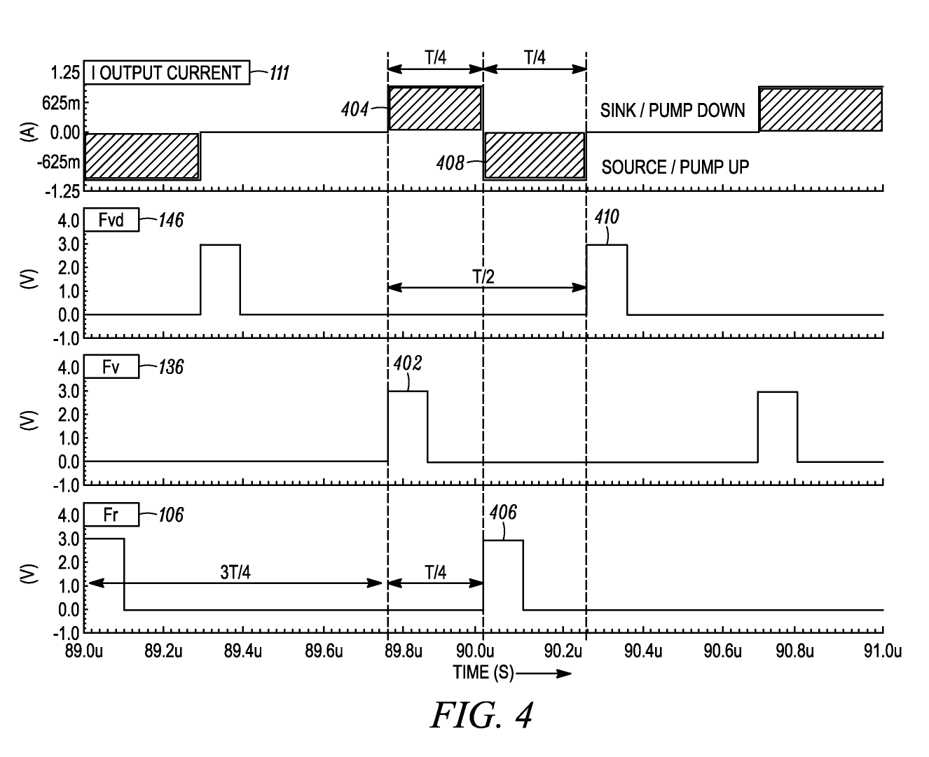

A generic, brief description of the operation of the control stage 200 is as follows. When the FV signal 136 and the FR signal 106 are within a locking range (FIG. 4), the control stage 200 first generates a PDC signal 234 having a duration of time followed by a PUC signal 222 having the same duration of time. Accordingly, a same amount of current is sourced as an amount that is sunk.

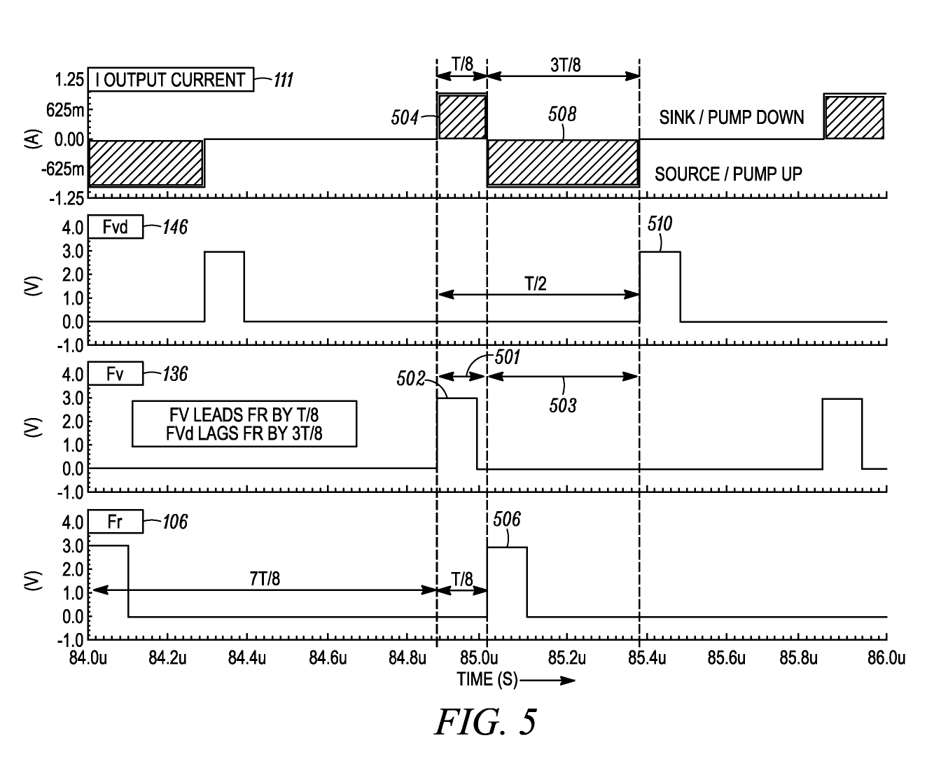

When the FV signal 136 leads the FR signal 106 by a lead time 501 and the FVd 146 signal lags the FR signal 106 by a lag time 503 (FIG. 5), the control stage 200 generates the PDC signal 234 having the active state with a duration that is essentially equal to the lead time 501, and then generates the PUC signal 222 having the active state with a duration that is essentially equal to the lag time 503 thereby producing a source current greater than the sink current.

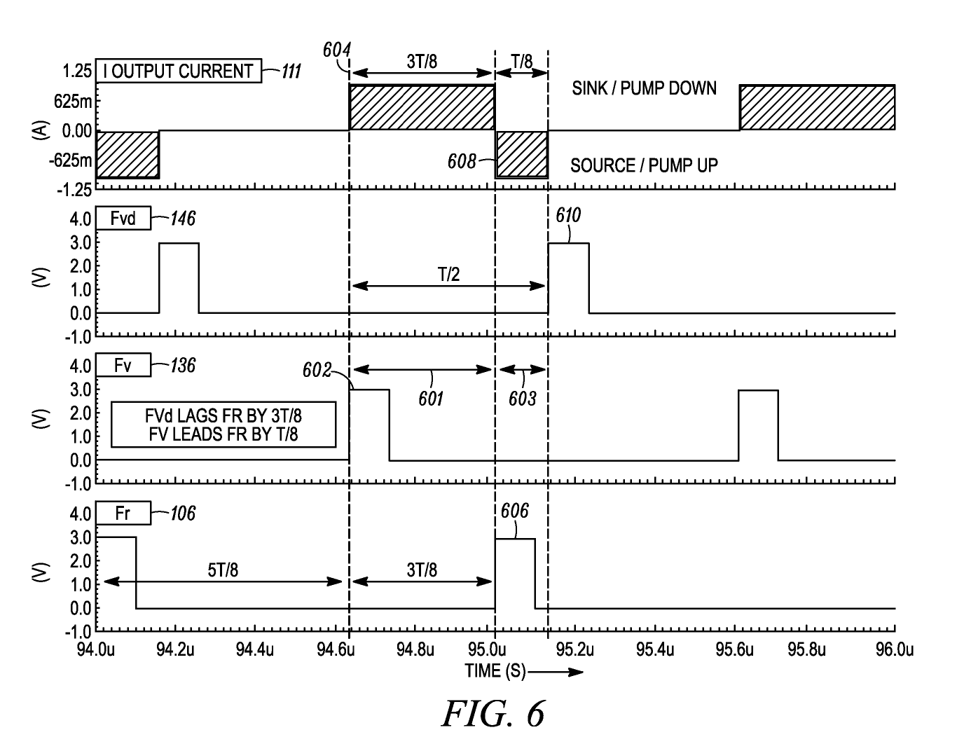

When the FV signal 136 leads the FR signal 106 by a lead time 601 and the FVd signal 146 lags the FR signal 106 by a lag time 603 (FIG. 6), the control stage 200 generates the PDC signal 234 having the active state with a duration that is essentially equal to the lead time 601, and then generates the PUC signal 222 having the active state with a duration that is essentially equal to the lag time 603 thereby producing a source current less than the sink current. A more detailed description of the operation of the control stage 200 is provided below, with reference to FIGS. 4, 5, and 6. It will be appreciated that the unique characteristics provided by the control stage 200 that have been described herein can be provided equally well by other combinations of sequential and combinational logic elements.

FIG. 4 is a timing diagram which illustrates signals generated by the control stage when the phase lock loop has acquired lock. Lock is acquired when the FV signal 136 and the FR signal 106 differ in phase by T/4, where T is the period of the FR signal 106. During lock, an amount of current flowing from the switched current source 350 over a time duration equals the amount of current flowing from the switched current sink 360 over the same time duration; that is, the output stage 300 sources the same amount of current as it sinks over a period of time. For example, when FV signal goes high 402, the output stage 300 sinks the current 404. Notably, the output current 111 shown in FIG. 4 is positive since the flow of electrons is opposite the flow of current. When the Fr signal then goes high 406, the output stage 300 sources the current 408 and simultaneously stops sinking the current. When the Fvd signal 146 goes high 410, the output stage stops sourcing the current, and the output current returns to zero.

Referring back to FIG. 2, when the Fv signal goes high 402, the forth flip-flop 216 is triggered to the active state Q4 which sends PDC 234 high and turns on the switched current sink 360 to sink current 404. The output current 111 shown in FIG. 4 is positive since the flow of electrons during a sink is opposite the direction of current flow. Since the Fr signal 106 is low the first flip-flop 210 is not active and PUC 222 is low. Accordingly, the switched current supply 350 is off.

When the Fr signal then goes high 406, the first flip-flop 210 is triggered to the active state Q1 which sends PUC 222 high and turns on the switched current source 350 to source current 408. The first AND gate 220 has only one high input (PUC) and therefore the RU signal 226 output by the AND gate is low. The switched current sink 360 is also turned off as a result of the Fr signal 106 going high. The output current 111 shown in FIG. 4 is negative since the flow of electrons during a source is in the direction of current flow. During this time, both the Fv signal 106 and the Fvd signal 146 are low.

The Fr signal 106 also triggers the third flip-flop 214 which causes the output of the second AND gate Reset Down (RD) 230 to go high. The second AND gate 230 has two high inputs and therefore the RD signal 236 output by the second AND gate is high. The RD signal 236 resets the third and the fourth flip-flop thereby sending PDC 234 low and turning off the switched current sink 360. Accordingly, when the switched current supply 350 is turned on, the switched current sink 360 is turned off.

When the Fvd signal goes high 410, the current source 350 is turned off. The Fvd signal 146 triggers the second flip-flop 212 which causes the output of the first AND gate Reset Up (RU) 220 to go high which resets the state of the first 210 and second 212 flip-flops. Consequently, this turns the PUC signal low which in turn stops the switched current source 350. At this time, no current is being sourced or sunk.

The current source and current sink are not on at the same times thereby reducing mismatch. Additionally, the duration of the PUC 222 signal is precisely controlled by the FR 106 signal and the FVd 146 signal, and the duration of the PDC 234 signal is precisely controlled by the FV 136 signal and the FR 106 signal, and the total duration of the PUC 222 signal and the PDC 234 signal combined is precisely controlled by the time delay between the FV 136 signal and the FVd 146 signal. This condition causes the output of the switched current source 350 and output of the switched current sink 360 to respond proportionally to phase changes of FV 136 relative to FR 106, both individually and in combination thereby preserving linearity of the phase detector 110.

Recall, the phase detector 110 estimates the phase difference between FV 136 and FR 106 for adjusting the frequency of Fvco 121 such that the average of the frequency of FV 136 matches the frequency of FR 106. The FV 136 and FR 106 signals represent the edges of the output frequency and reference frequency. Thus, the output current 111 undergoes a positive (404) and negative (408) change at cycles of the output signal frequency. Notably, the UP and DOWN pulses are applied at intervals corresponding to the cycle of the output frequency. Understandably, the phase detector 110 can pulse up or down at precise time intervals around the cycles of the output frequency. In this configuration, the control stage 200 can rapidly react to small changes in phase introducing noise only when a pulse up or pulse down is present. Recall, in FIG. 1, that the variable frequency delay counter 147 provides a well controlled and programmable time shift relative to the loop divider output signal FV 136. This time shift creates a linear region in the phase detector transfer function so that the output pulses which source and sink current are both provided. For example, the current output 111 in the first subplot of FIG. 4 shows that an equal amount of current is sourced and sunk when the PLL 100 is in phase lock.

The precise time shift provided by the variable frequency delay counter 147 is programmed to minimize the durations of the output current pulses, I₁ and I₂, thereby minimizing added noise and spurious behaviors due to the variable modulus divider. Furthermore, the variable frequency delay counter 147 can obtain the delayed signal directly from a fast edge of the Fvco output 121, without the use of an analog delay element. As a result, Fvco does not suffer from noise degradation associated with an analog delay elements. In practice, both the UP and DOWN pulses contribute the same level of gain and noise, therefore, resulting in an improved signal-to-noise ratio. The variable frequency delay counter 147 introduces a well controlled phase offset that is independent of nearly all operating loop parameters and conditions. Additionally, the average current versus phase transfer function 300 is symmetrical outside the linear region 310 and as a result, it is capable of achieving fast frequency and phase acquisition without degradation from phase offset problems existing in other approaches.

FIG. 5 is a timing diagram which illustrates the signals generated by control stage 200 and control stage 300 when the FV edge 502 occurs earlier than the FR edge 506; that is, a lead time 501 of T/8 and the FVd edge 510 occurs later than the FR edge 506 by a lag time of 3T/8. During lead time 501, the output stage 300 sinks proportionally less current than it proportionally sources during the lag time 503 in response to FV arriving later than in FIG. 4. Notably, the output current 111 is positive for a current sink and negative for a current source since the flow of electrons is opposite the direction of current flow. When the FV edge arrives late, the amount of current sunk is reduced and the amount of current sourced is increased relative to the amount of current sunk and sourced at equilibrium. For example, when FV 136 goes high 502, the output current is sunk 504 until an edge of FR 106 is received. When FR 106 goes high 506, the output current is sourced 508 until an edge of FVd 146 is received. Notably, the duration of the sourcing interval (508) is greater than the duration of the sinking interval (504) and the total duration of sourcing interval (508) and sinking interval (504) is a constant defined by the time interval between the FV edge 502 and the FVd edge 510.

Referring back to FIG. 2, when the Fv signal goes high 502, the forth flip-flop 216 is triggered to the active state Q4 which sends PDC 234 high and turns on the switched current sink 360 to sink current 504. Since the Fr signal 106 is low the first flip-flop 210 is not active and PUC 222 is low. Accordingly, the switched current supply 350 is off.

When the Fr signal then goes high 506, the first flip-flop 210 is triggered to the active state Q1 which sends PUC 222 high and turns on the switched current source 350 to source current 508. The first AND gate 220 has only one high input (PUC) and therefore the RU signal 226 output by the AND gate is low. The switched current sink 360 is also turned off as a result of the Fr signal 106 going high. During this time, both the Fv signal 106 and the Fvd signal 146 are low. The Fr signal 106 also triggers the third flip-flop 214 which causes the output of the second AND gate Reset Down (RD) 230 to go high. The second AND gate 230 has two high inputs and therefore the RD signal 236 output by the second AND gate is high. The RD signal 236 resets the third and the fourth flip-flop thereby sending PDC 234 low and turning off the switched current sink 360. Accordingly, when the switched current supply 350 is turned on, the switched current sink 360 is turned off. The current source and current sink are not on at the same times thereby reducing mismatch and preserving linearity of the phase detector 110.

When the Fvd signal goes high 510, the current source 350 is turned off. The Fvd signal 146 triggers the second flip-flop 212 which causes the output of the first AND gate Reset Up (RU) 220 to go high which resets the state of the first 210 and second 212 flip-flops. Consequently, this turns the PUC signal low which in turn stops the switched current source 350. At this time, no current is being sourced or sunk.

FIG. 6 is a timing diagram which illustrates the signals generated by control stage 200 and control stage 300 when the FV edge 602 occurs earlier than the FR edge 606; that is, a lead time 601 of 3T/8 and the FVd edge 610 occurs later than the FR edge 606 by a lag time 603 of T/8. During the lead time 601, the output stage 300 sinks proportionally more current than it proportionally sources during the lag time 603 in response to FV arriving earlier than in FIG. 4. Notably, the output current 111 is positive for a current sink and negative for a current source since the flow of electrons is opposite the direction of current flow. When the FV edge 602 arrives early, the amount of current sunk is increased and the amount of current sourced is decreased relative to the amount of current sunk and sourced at equilibrium. For example, when FV 136 goes high 602, the output current is sunk 604 until an edge of FR 106 is received. When Fr 106 goes high 606, the output current is sourced 608. Notably, the duration of the sinking interval (604) is greater than the duration of the sourcing interval (608) and the total duration of sourcing interval (608) and sinking interval (604) is a constant defined by the time interval between the FV edge 602 and the FVd edge 610. With regard to FIG. 2, the operative conditions of the flip-flop and logic elements are applied similarly.

Where applicable, the present embodiments of the invention can be realized in hardware, software or a combination of hardware and software. Any kind of computer system or other apparatus adapted for carrying out the methods described herein are suitable. A typical combination of hardware and software can be a mobile communications device with a computer program that, when being loaded and executed, can control the mobile communications device such that it carries out the methods described herein. Portions of the present method and system may also be embedded in a computer program product, which comprises all the features enabling the implementation of the methods described herein and which when loaded in a computer system, is able to carry out these methods.

While the preferred embodiments of the invention have been illustrated and described, it will be clear that the embodiments of the invention are not so limited. Numerous modifications, changes, variations, substitutions and equivalents will occur to those skilled in the art without departing from the spirit and scope of the present embodiments of the invention as defined by the appended claims.

What is claimed is:

1. A phase-frequency detector, comprising:
an output stage for generating an output signal;
a control stage coupled to the output stage that generates, in response to receiving a divided variable frequency delayed signal (FVd), a divided variable frequency signal (FV), and a reference frequency signal (FR), a pump up control signal and a pump down control signal,
wherein when the FV leads the FR by a lead time and FVd lags FR by a lag time, the control stage generates the pump down control signal having an active state with a duration that is essentially equal to the lead time, and generates the pump up control signal having an active state with a duration that is essentially equal to the lag time.

2. The phase-frequency detector according to claim 1, further comprising:
a frequency counter delay for counting cycles of a loop divider input signal and generating the divided variable frequency delayed signal (FVd) signal from the FV signal, wherein FVd is a replica of FV and has a delay that corresponds to a predetermined number of cycles.

3. The phase-frequency detector according to claim 1, wherein the control stage comprises:
a first flip-flop, having a clock input coupled to the FR, wherein the first flip-flop that is set to the active state in response to an edge of the FR generates a pump up control signal;
a second flip-flop, having a clock input coupled to the FVd, wherein the second flip-flop that is set to an active state in response to an edge of the FVd generates a trigger up signal;
a third flip-flop, having a clock input coupled to the FR, wherein the third flip-flop that is set to an active state in response to an edge of the FR generates a trigger down signal; and
a fourth flip-flop, having a clock input coupled to the FV wherein the fourth flip-flop that is set to the active state in response to an edge of the FV generates a pump down control signal.

4. The phase-frequency detector according to claim 3, wherein the control stage comprises:
a first AND gate that has the pump up control signal and the trigger up signal coupled thereto as inputs; and
wherein the first flip-flop has a first reset input that is coupled to the output of the first AND gate, and
wherein the second flip-flop has a second reset input that is coupled to the output of the first AND gate.

5. The phase-frequency detector according to claim 3, wherein the control stage comprises:
a second AND gate that has the trigger down signal and the pump down control signal coupled thereto as inputs; and
wherein the third flip-flop has a third reset input that is coupled to the output of the second AND gate, and
wherein the fourth flip-flop has a fourth reset input that is coupled to the output of the second AND gate.

6. The phase-frequency detector according to claim 1, wherein the phase-frequency detector is implemented in one integrated circuit.

7. The phase-frequency detector according to claim 1, wherein the output stage comprises a pump up switched current source coupled to a charge pump output node that sources a first current, I1, in response to a pump up control signal, a pump down switched current sink coupled to the charge pump output node that sources a second current, I2, in response to a pump down control signal, at the charge pump output node.

8. The phase-frequency detector according to claim 7, wherein during a phase lock the pump down control signal and the pump up control contribute an approximately equal amount of gain to the output signal when the first current and the second current are approximately the same.

9. A phased lock loop comprising:
a phase-frequency detector that comprises:
a first input to a control stage that receives a reference frequency signal (FR);
a second input to the control stage that receives a divided variable frequency signal (FV);
a third input to the control stage that receives a divided variable frequency delayed signal (FVd) signal; and
an output stage coupled to the control stage, wherein the output stage generates an output signal having a current in proportion to a phase difference between the FR and the FV;
a frequency counter delay for counting cycles of the loop divider input signal and generating the divided variable frequency delayed signal (FVd) signal from the FV signal, wherein the FVd has a delay that corresponds to a predetermined number of cycles,
wherein the control stage generates, in response to a divided variable frequency signal (FV), a reference frequency signal (FR) and the FVd signal, a pump up control signal and a pump down control signal,
wherein when the FV lags the FR by a lag time, the control stage generates the pump up control signal having the active state with a duration that is essentially equal to the lag time, and generates the pump down control signal having the active state with a duration determined by the FVd,
wherein when the FV leads the FR by a lead time, the control stage generates the pump down control signal having the active state with a duration that is essentially equal to the lead time, and generates the pump up control signal having the active state with a duration determined by the FVd, and
wherein when the FV and the FR are approximately concurrent in time, the duration of the pump up control signal is essentially equal to the duration of the pump down control signal.

10. The phased lock loop of claim 9, wherein during a phase lock the pump up control signal sources a first current and the pump down control signal sinks a second current that contribute a substantially equal amount to a gain of the output signal when the first current and the second current are approximately equal.

11. The phased lock loop of claim 10, wherein a linearity of the phase-frequency detector is maintained when the first current and the second current are mismatched.

12. The phased lock loop of claim 9, wherein the frequency counter delay counts cycles of a loop divider input signal and generates the divided variable frequency delayed signal (FVd) signal from the FV signal, wherein FVd is a replica of FV and has a delay that corresponds to a predetermined number of cycles.

13. The phased lock loop of claim 9, wherein the frequency counter delay generates a phase offset that is directly proportional to a cycle of the loop divider input signal.

14. The phased lock loop of claim 9, wherein the frequency counter delay counts cycles of the output signal and generates a carry flag on a number of counted cycles, wherein the carry flag triggers the control stage to establish the duration for one of the pump control signals.

15. The phased lock loop of claim 14, wherein the frequency counter delay detects the occurrence of a state that precedes the carry by a predetermined number of counts, wherein the number of counted cycles is a programmable time shift relative to the FV signal.

16. An electronic equipment comprising a phase-frequency detector comprising an output stage that comprises:
a pump up switched current source coupled to a charge pump output node that sources a first current, I1, in response to a pump up control signal;
a pump down switched current sink coupled to the charge pump output node that sources a second current, I2, in response to a pump down control signal; and
a control stage coupled to the output stage that generates, in response to a divided variable frequency delayed signal (FVd) signal, a divided variable frequency signal (FV), and a reference frequency signal (FR), a pump up control signal and a pump down control signal,
wherein during a phase lock the pump up control signal sources a first current and the pump down control signal sinks a second current that contribute a substantially equal amount to a gain of the output signal when the first current and the second current are approximately equal.

17. The electronic equipment of claim 16, wherein the control stage comprises:
a frequency counter delay for counting cycles of the loop divider input signal to generate the divided variable frequency delayed signal (FVd),
wherein during the phase lock, the duration of the pump up control signal is essentially equal to the duration of the pump down control signal.

18. The phased lock loop of claim 17, wherein the frequency counter delay generates a phase offset that is directly proportional to a cycle of the loop divider input signal.

19. The electronic equipment of claim 16, wherein the phase offset is obtained from an edge of the loop divider input signal.

20. The electronic equipment of claim 16, wherein the phase offset is obtained from an edge of the output signal to increase a lock time.
